(19) United States
(12) Patent Application Publication
(10) Pub. No.: US 2019/0081640 A1
(43) Pub. Date: Mar. 14, 2019

(54) FAULTY WORD LINE AND FAULTY BIT LINE INFORMATION IN ERROR CORRECTING CODING

(71) Applicant: Intel Corporation, Santa Clara, CA (US)

(72) Inventor: RAVI H. MOTWANI, Fremont, CA (US)

(73) Assignee: Intel Corporation, Santa Clara, CA (US)

(21) Appl. No.: 15/699,939

(22) Filed: Sep. 8, 2017

(51) Int. Cl. H03M 13/11; G06F 11/10; H03M 13/00

(52) U.S. Cl. CPC H03M 13/1111; H03M 13/611; G06F 11/10

(57) ABSTRACT

One embodiment provides a memory controller. The memory controller includes a memory controller control circuitry, a defect map logic and an error correction circuitry. The memory controller circuitry is to read a codeword from a memory device. The defect map logic is to identify a respective word line (WL) and a respective bit line (BL) for each bit in the codeword based, at least in part, on a memory device map and to determine whether any identified WL and/or any identified BL is faulty based, at least in part, on a defect map. The error correction circuitry is to configure a decode operation if any identified WL and/or any identified BL is faulty.

### FIELD

The present disclosure relates to error correcting coding, in particular to, faulty word line and faulty bit line information in error correcting coding.

### BACKGROUND

A memory device may include a plurality of memory cells accessed via a plurality of word lines (WLs) and a plurality of bit lines (BLs). Each WL and each BL is associated with a plurality of memory cells. Thus, a faulty WL and/or a faulty BL may result in a plurality of memory read errors and may thus adversely affect a raw bit error rate (RBER) for the memory device.

### BRIEF DESCRIPTION OF DRAWINGS

Features and advantages of the claimed subject matter will be apparent from the following detailed description of embodiments consistent therewith, which description should be considered with reference to the accompanying drawings, wherein:

FIG. 1A illustrates a functional block diagram of a system that includes a memory device and a defect map circuitry consistent with several embodiments of the present disclosure;

FIG. 1B illustrates an example tile corresponding to any tile of the memory device of FIG. 1A;

FIGS. 2A and 2B are flowcharts of defect map operations according to various embodiments of the present disclosure; and

FIG. 3 is a flowchart of error correction operations according to various embodiments of the present disclosure.

Although the following Detailed Description will proceed with reference being made to illustrative embodiments, many alternatives, modifications, and variations thereof will be apparent to those skilled in the art.

### DETAILED DESCRIPTION

Error correction circuitry may be configured to encode data bits (information to be stored) with a number of parity bits into a codeword. The parity bits are configured to facilitate decoding the codeword to recover the data bits in the presence of one or more bit errors. The encoding may comply and/or be compatible with a selected error correcting code. The codeword may then be stored in a memory device. The plurality of bits of the codeword may be distributed across the memory device. In other words, the plurality of bits included in the codeword may not share a word line (WL) nor a bit line (BL).

In response to a read request, the codeword may be retrieved from the memory device. The error correction circuitry may then be configured to decode the codeword to recover the data bits. Due to nonideal characteristics of the memory device, the retrieved codeword may include one or more error bits. For example, a faulty WL and/or a faulty BL may result in a plurality of bit errors (“faulty bits”) distributed across a plurality of codewords. The decoding may thus include detection and/or correction of the one or more error bits.

Generally, this disclosure relates to faulty WL and faulty BL information in error correcting coding. An apparatus, method and/or system may be configured to identify a faulty WL and/or a faulty BL and to include a faulty WL identifier and/or a faulty BL identifier in a defect map. The apparatus, method and/or system may then be configured to utilize the defect map to inform error correction circuitry which bits, if any, in a codeword are faulty bits. Faulty bits may be bits associated with the faulty WL and/or faulty BL. The error correction circuitry may then be configured to utilize this faulty bit information to configure a decode operation. The configuration of the decode operation may be related to a selected error correcting code, as will be described in more detail below. In one example, the faulty bits may be erased, thus reducing latency associated with decoding operations. In another example, the error correction circuitry may be configured to perform a number of decode attempts. The number of decode attempts may be related to the number of faulty bits in the codeword. The number of attempts may correspond to at least a portion of all possible combinations of values for the faulty bits.

Thus, a defect map that includes identifiers corresponding to faulty WLs and/or faulty BLs may be utilized to facilitate codeword decoding and error correction operations. Erasing faulty bits may improve latency for error correcting codes that can accommodate erasures. Identifying faulty bits may reduce a raw bit error rate (RBER) by facilitating decoding for error correcting codes that cannot accommodate erasures.

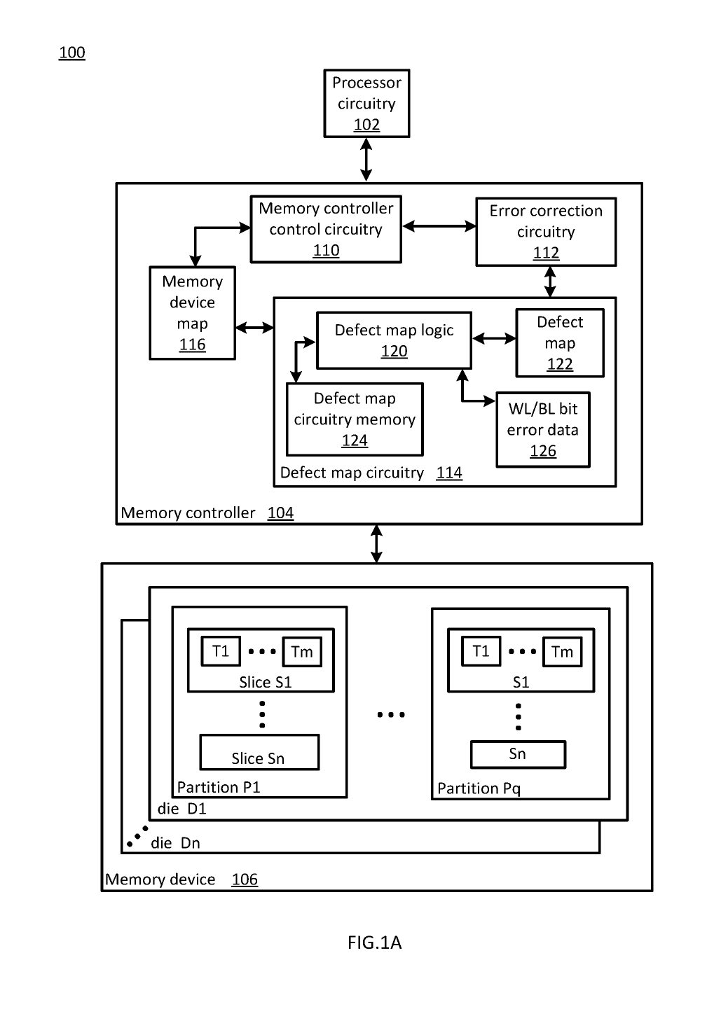

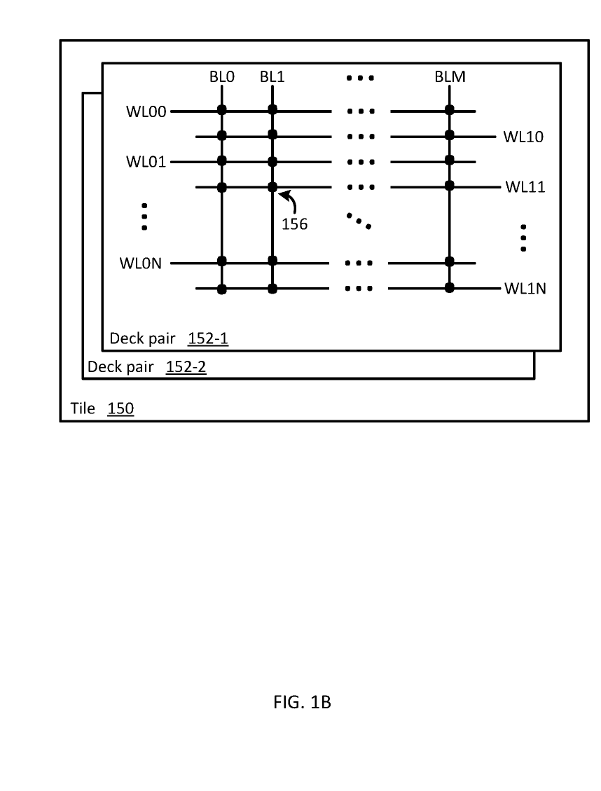

FIG. 1A illustrates a functional block diagram of a system 100 that includes a defect map circuitry consistent with several embodiments of the present disclosure. System 100 may correspond to, and/or be included in, a mobile telephone including, but not limited to a smart phone (e.g., iPhone®, Android®-based phone, Blackberry®, Symbian®-based phone, Palm®-based phone, etc.); a wearable device (e.g., wearable computer, “smart” watches, smart glasses, smart clothing, etc.) and/or system; a computing system (e.g., a server, a workstation computer, a desktop computer, a laptop computer, a tablet computer (e.g., iPad®, GalaxyTab® and the like), an ultraportable computer, an ultramobile computer, a netbook computer and/or a subnotebook computer; etc.

System 100 includes a processor circuitry 102, a memory controller 104 and a memory device 106. For example, processor circuitry 102 may correspond to a single core or a multi-core general purpose processor, such as those provided by Intel® Corp., etc. Memory controller 104 may be coupled to and/or included in processor circuitry 102 and may be configured to couple processor circuitry 102 to memory device 106.

Memory device 106 may include a non-volatile memory, e.g., a storage medium that does not require power to maintain the state of data stored by the storage medium. Nonvolatile memory may include, but is not limited to, a NAND flash memory (e.g., a Triple Level Cell (TLC) NAND or any other type of NAND (e.g., Single Level Cell (SLC), Multi Level Cell (MLC), Quad Level Cell (QLC), etc.)), NOR memory, solid state memory (e.g., planar or three Dimensional (3D) NAND flash memory or NOR flash memory), storage devices that use chalcogenide phase change material (e.g., chalcogenide glass), byte addressable nonvolatile memory devices, ferroelectric memory, silicon-oxide-nitride-oxide-silicon (SONOS) memory, polymer memory (e.g., ferroelectric polymer memory), byte addressable random accessible 3D crosspoint memory, ferroelectric transistor random access memory (Fe-TRAM), magnetoresistive random access memory (MRAM), phase change memory (PCM, PRAM), resistive memory, ferroelectric memory (F-RAM, FeRAM), spin-transfer torque memory (STT), thermal assisted switching memory (TAS), millipede memory, floating junction gate memory (FJG RAM), magnetic tunnel junction (MTJ) memory, electrochemical cells (ECM) memory, binary oxide filament cell memory, interfacial switching memory, battery-backed RAM, ovonic memory, nanowire memory, electrically erasable programmable read-only memory (EEPROM), etc. In some embodiments, the byte addressable random accessible 3D crosspoint memory may include a transistor-less stackable cross point architecture in which memory cells sit at the intersection of words lines and bit lines and are individually addressable and in which bit storage is based on a change in bulk resistance.

Processor circuitry 102 may be configured to provide a memory access request, e.g., a write request and/or a read request, to memory controller 104. For example, the read request may include address information for data to be read from a memory location in memory device 106 that corresponds to the address information. The memory controller 104 may then be configured to manage reading the data from the memory device 106.

Memory controller 104 includes a memory controller control circuitry 110, error correction circuitry 112, defect map circuitry 114 and memory device map 116. The memory controller control circuitry 110 is configured to determine an address of a target memory cell in response to a memory access request from processor circuitry 102. The memory controller control circuitry 110 is further configured to identify a WL and a BL that correspond to the address of the target memory cell based, at least in part, on the determined address and a based, at least in part, on memory device map 116. Memory device map 116 is configured to relate a memory cell address to a WL identifier and a BL identifier. Thus, memory device map 116 may include an array of addresses with each address associated with a respective WL identifier and a respective BL identifier that corresponds to the memory cell associated with the address. The memory controller control circuitry 110 is further configured to select the target memory cell(s) and to write to or read from the selected target memory cell(s). The selecting, writing and/or reading may include driving the identified WL and/or identified BL to accommodate the memory access operation.

Memory controller control circuitry 110 is configured to receive data to be written to memory device 106 from processor circuitry 102, e.g., in response to a write request. Memory controller control circuitry 110 may then be configured to provide the data to be written to error correction circuitry 112. Error correction circuitry 112 may be configured to encode the data to be written using an error correcting code to generate a corresponding codeword. The codeword may thus include a plurality of data bits and a plurality of error correction bits. The data bits correspond to information bits and the error correction bits correspond to parity bits. In one embodiment, the error correcting code may comply and/or be compatible with a low density parity check (LDPC) error correcting code. In another embodiment, the error correcting code may comply and/or be compatible with a Reed-Solomon error correcting code. In another embodiment, the error correcting code may comply and/or be compatible with a Bose-Chaudhuri-Hocquenghem (BCH) error correcting code.

Memory controller control circuitry 110 may then be configured to store the corresponding codeword in memory device 106. Memory controller control circuitry 110 may be configured to read the codeword in response to a read request and to provide the received codeword to error correction circuitry 112. Error correction circuitry 112 may then be configured to decode the received codeword.

Memory device 106 includes a plurality of dies, D1, . . . , Dn. Each die, e.g., D1, includes a plurality of partitions, P1, . . . , Pq. Each partition, e.g., partition P1, includes a plurality of slices, S1, . . . , Sn. Each slice, e.g., slice S1, includes a plurality of tiles T1, . . . , Tm. In one nonlimiting example, each die, e.g., die D1, may include 32 partitions; each partition, e.g., partition P1, may include four slices; and each slice, e.g., slice S1, may include 128 tiles. The values n, q and m may be whole number integers greater than or equal to 1.

FIG. 1B illustrates an example tile 150 corresponding to any tile T1, . . . , Tm, of the memory device 106 of FIG. 1A. Example tile 150 includes two deck pairs 152-1, 152-2. In other examples, a tile may include more or fewer deck pairs. Each deck pair, e.g., deck pair 152-1 includes a first plurality of word lines (WLs) WL00, WL01, . . . , WL0N, a second plurality of word lines WL10, WL11, . . . , WL1N, a plurality of bit lines (BL) BL0, BL1, . . . , BLM and a plurality of memory cells, e.g., memory cell 156. Each WL may cross a BL at a memory cell, e.g., memory cell 156. For example, the first plurality of WLs WL00, WL01, . . . , WL0N, the plurality of BLs BL0, BL1, . . . , BLM and the corresponding plurality of memory cells may correspond to a first deck and the second plurality of WLs WL10, WL11, . . . , WL1N, the plurality of BLs BL0, BL1, . . . , BLM and the corresponding plurality of memory cells may correspond to a second deck of deck pair 152-1. Thus, each deck 152-1, 152-2 may include an array of memory cells and memory device 106 may include a plurality of decks. In one nonlimiting example, each tile, e.g., tile 150, may include 4000 WLs and 2000 BLs in four decks.

Turning again to FIG. 1A, defect map circuitry 114 includes defect map logic 120, a defect map 122, defect map circuitry memory 124 and WL/BL bit error data 126. Defect map logic 120 is configured to generate and/or update defect map 122, to provide defect map information to error correction circuitry 112 and to update WL/BL bit error data 126, as will be described in more detail below. Defect map circuitry memory 124 may be configured to contain defect map 122 and/or WL/BL bit error data 126. Defect map 122 is configured to contain WL and/or BL identifiers for each WL and/or each BL that has been identified as faulty. WL/BL bit error data 126 is configured to contain bit error data that may then be utilized by defect map logic 120 identify a faulty WL and/or a faulty BL. WL/BL bit error data 126 may be configured to store bit error data for a WL and/or a BL that has a raw bit error rate (RBER) that is less than a threshold RBER. If the respective RBER increases to equal to or greater than the threshold RBER so that the associated WL and/or associated BL is identified as faulty, the corresponding bit error data may then be deleted.

In operation, in response to a read request from processor circuitry 102, memory controller control circuitry 110 may be configured to read a codeword from memory device 106. For example, memory controller control circuitry 110 may receive address information corresponding to an address of data to be read. Memory controller control circuitry 110 may then be configured to determine the address. Memory controller control circuitry 110 may then be configured to identify each WL and each BL associated with the address, utilizing memory device map 116. It may be appreciated that an address that corresponds to one codeword may be associated with a plurality of bits. One or more bits may be stored in each of a plurality of memory cells. The memory cells may then be distributed across memory device 106. In one example, the memory cells may be randomly distributed across the memory device 106. In another example, each memory cell may be positioned in a same respective location in each tile of a plurality of tiles in one partition. Other distributions of memory cells for a stored codeword are equally contemplated herein.

Memory controller control circuitry 110 may then be configured provide the codeword to error correction circuitry 112. Error correction circuitry 112 may be ignorant of the locations in memory device 106 of the bits of the received codeword. Defect map logic 120 may then be configured to retrieve or receive the address of the codeword. The address may be provided by or retrieved from the memory controller control circuitry 110.

Defect map logic 120 may then be configured to identify a respective WL and a respective BL for each bit in the codeword. For example, defect map logic 120 may be configured to access the memory device map 116 and to identify each respective WL and respective BL associated with the address. Defect map logic 120 may then be configured to determine whether any identified WL and/or any identified BL is faulty. For example, defect map logic 120 may be configured to access defect map 122 to make the determination.

Defect map 122 is configured to contain WL identifier(s) corresponding to faulty WL(s) and/or BL identifier(s) corresponding to faulty BL(s). Defect map logic 120 may be configured to determine whether a WL identifier corresponding to any identified WL and/or a BL identifier corresponding to any identified BL is contained in the defect map 122. If defect map 122 contains a WL identifier corresponding to an identified WL and/or a BL identifier corresponding to an identified BL, defect map logic 120 may be configured to notify error correction circuitry 112. The notification is configured to include a respective bit identifier for each bit of the codeword, i.e., “faulty bit”, that is associated with an identified faulty WL and/or an identified faulty BL. Thus, error correction circuitry 112 may be provided a respective identifier for each faulty bit included in the codeword.

If a notification of faulty bit(s) is provided to the error correction circuitry 112, the error correction circuitry 112 may configure a decode operation based, at least in part, on a selected error correcting code. In other words, error correction circuitry 112 may be configured to implement one or more error correcting codes. The error correcting codes may include, but are not limited to, LDPC, Reed Solomon, BCH, etc. It may be appreciated that different error correcting codes may have different characteristics and/or different capabilities. For example, LDPC and/or Reed Solomon are capable of managing erasures. An erasure corresponds to a bit that cannot be read due to a failure in the memory device, e.g., a faulty WL and/or a faulty BL. “Knowledge” of a respective bit location of each erasure in a codeword may be utilized by LDPC and/or Reed Solomon to speed up the decode process and to thus reduce latency. In another example, BCH may be unable to successfully decode a codeword in the presence of erasures. Thus, in one example, error correction circuitry 112 may configure the decode operation by erasing the faulty bit(s), if the error correcting code complies and/or is compatible with LDPC or Reed Solomon error correcting code.

In another example, error correction circuitry 112 may configure the decode operation to attempt to decode the codeword using at least a portion of a number of possible values of the faulty bit(s), if the error correcting code complies and/or is compatible with BCH error correcting code. For example, if the codeword includes two faulty bits, the error correction circuitry 112 may configure the decode operation to attempt to decode the codeword using up to the four possible combinations of two faulty bits (i.e., 00, 01, 10, 11). Error correction circuitry 112 may then be able to successfully decode the codeword with one combination of values of faulty bits. Successfully decoding the codeword may then not impact an uncorrectable bit error rate (UBER). Thus, error correction circuitry 112 may then decode the codeword utilizing the decode operation that has been configured based, at least in part, on a selected error correcting code.

Error correction circuitry 112 is configured to determine whether the codeword contains any error bits that do not correspond to faulty bits. Error bits that do not correspond to faulty bits are error bits that are not associated with any identified faulty WL or any identified faulty BL. If the codeword does contain error bits that do not correspond to faulty bits, error correction circuitry 112 is configured to notify defect map circuitry 114 (i.e., defect map logic 120). Defect map logic 120 may then be configured to retrieve or receive a respective location of each error bit in the decoded codeword. For example, the respective location of each error bit may be retrieved from error correction circuitry 112 by defect map logic 120 or may be provided to defect map logic 120 by error correction circuitry 112.

Defect map logic 120 may then be configured to update WL/BL bit error data 126 for each error bit. As used herein, “WL/BL” corresponds to “WL and/or BL”. WL/BL bit error data 126 is configured to include a WL identifier and corresponding WL bit error data and/or a BL identifier and corresponding BL bit error data for each error bit identified by error correction circuitry 112. The WL/BL bit error data 126 is configured to include a respective indicator for each bit associated with the WL identifier or the BL identifier. In other words, for each WL identifier and/or BL identifier, the WL/BL bit error data 126 is configured to include an indicator (e.g., bit) for each memory cell associated with the WL and/or BL. The indicator is configured to indicate whether the associated bit as been identified as an error bit by error correction circuitry 112. Defect map logic 120 is configured to set a bit error indicator for any error bit not already set in WL/BL bit error data.

Defect map logic 120 may then be configured to utilize WL/BL bit error data 126 to determine whether a corresponding WL and/or a corresponding BL is faulty. Whether a corresponding WL and/or a corresponding BL is faulty may be determined based, at least in part, on WL bit error data and/or BL bit error data. Whether the corresponding WL and/or corresponding BL is faulty may be determined further based, at least in part, on a threshold RBER. An RBER for a corresponding WL and/or a corresponding BL may be determined as a ratio of a number of error bits to a total number of bits associated with the corresponding WL and/or corresponding BL. If the RBER for the corresponding WL and/or the corresponding BL is greater than or equal to the respective corresponding threshold RBER, then the corresponding WL and/or corresponding BL may be deemed faulty by the defect map logic 120. The threshold RBER may be in the range of 10 percent (%) to 50%. In one nonlimiting example, the threshold RBER may be equal to 30%.

If the corresponding WL and/or the corresponding BL is faulty, the defect map logic 120 is configured to update the defect map 122. For example, the defect map 122 may be updated by adding a WL identifier corresponding to a faulty WL and/or a BL identifier corresponding to a faulty BL to the defect map 122. If the corresponding WL and/or the corresponding BL is faulty, defect map logic 120 is configured to update WL/BL bit error data 126. For example, the WL/BL bit error data 126 may be updated by deleting the WL identifier and associated WL bit error data of a corresponding faulty WL and/or deleting the BL identifier and associated BL bit error data of a corresponding faulty BL. Thus, storage capacity associated with the WL/BL bit error data 126 may be maintained.

Thus, a defect map that includes identifiers corresponding to faulty WLs and/or faulty BLs may be utilized to facilitate codeword decode and error correction operations. Erasing faulty bits may improve latency for error correcting codes that can accommodate erasures. Identifying faulty bits may reduce an RBER by facilitating decoding for error correcting codes that cannot accommodate erasures.

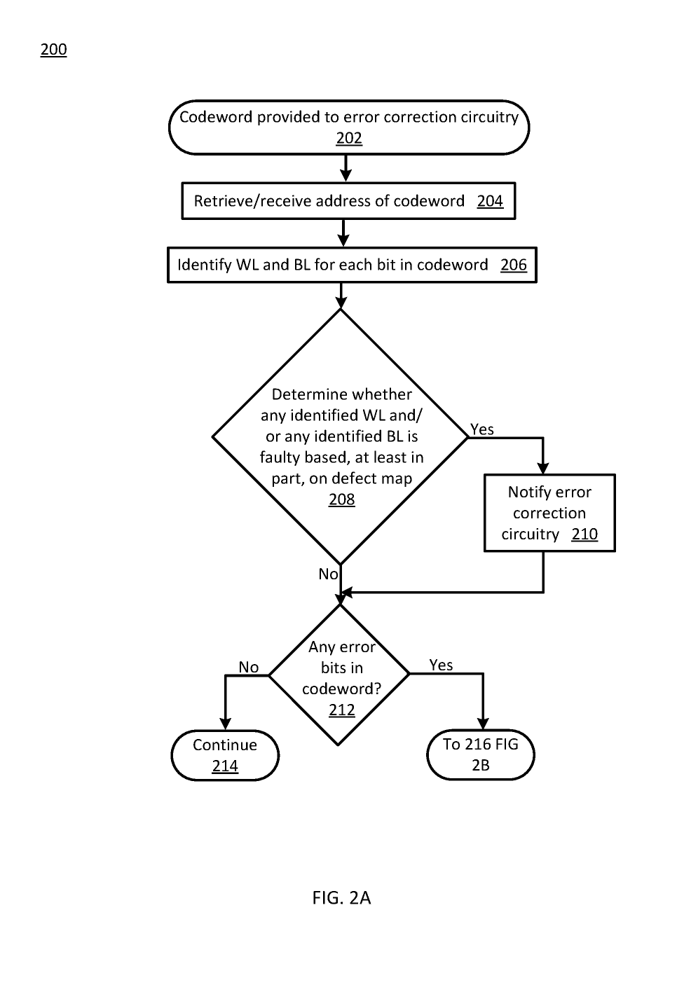

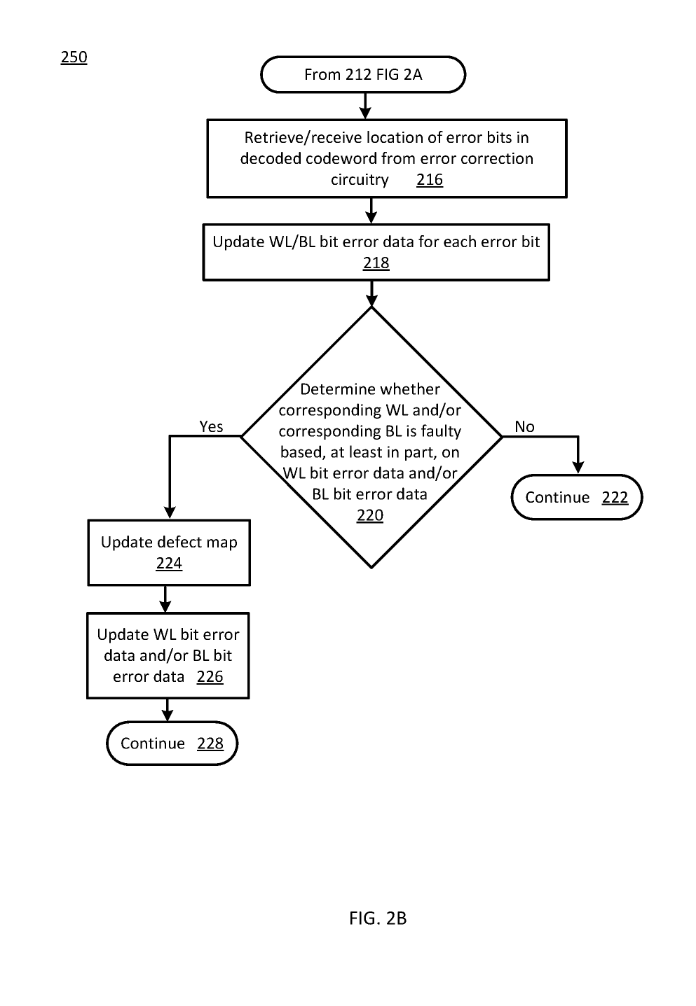

FIGS. 2A and 2B are flowcharts 200, 250 of defect map operations according to various embodiments of the present disclosure. FIG. 2B is a continuation of FIG. 2A, thus, FIGS. 2A and 2B may be best understood when considered together. In particular, the flowcharts 200, 250 illustrate identifying faulty WLs and/or BLs, providing faulty bit information to an error correction circuitry and maintaining and updating a defect map. The operations may be performed, for example, by elements of defect map circuitry 114, e.g., defect map logic 120, of FIG. 1A.

Operations of this embodiment may begin with a codeword provided to error correction circuitry at operation 202. For example, memory controller control circuitry may be configured to read a codeword from a memory device and to provide the codeword to the error correction circuitry. Operation 204 includes retrieving or receiving an address of the codeword. For example, the address may be received or retrieved from the memory controller control circuitry. A WL and a BL may be identified for each bit in the codeword at operation 206. For example, the identifying may be performed utilizing a memory device map. Whether any identified WL and/or any identified BL is faulty may be determined based, at least in part, on a defect map at operation 208. If an identified WL and/or an identified BL is faulty, error correction circuitry may be notified at operation 210. Program flow may then proceed to operation 212.

If none of the identified WLs and none of the identified BLs are determined to be faulty, program flow may then proceed to operation 212. Whether the codeword contains any error bits may be determined at operation 212. For example, error correction circuitry may be configured to provide an indication of the presence of error bits, if any, in the codeword to the defect map logic. If there are no error bits in the codeword then program flow may continue at operation 214.

Turning now to FIG. 2B, if there are error bits in the codeword, a respective location of each error bit in the decoded codeword may be retrieved or received from the error correction circuitry at operation 216. WL/BL bit error data may be updated for each error bit at operation 218. For example, a bit error indicator may be set for any error bit not already set in WL/BL bit error data. Whether a corresponding WL and/or a corresponding BL is faulty may be determined based, at least in part, on WL bit error data and/or BL bit error data at operation 220. If neither the corresponding WL nor the corresponding BL is faulty then program flow may continue at operation 222. If the corresponding WL and/or the corresponding BL is faulty, the defect map may be updated at operation 224. The WL bit error data and/or BL bit error data may be updated at operation 226. Program flow may then continue in operation 228.

Thus, a faulty WL and/or a faulty BL may be identified and associated faulty bit information may be provided to error correction circuitry. The error correction circuitry is configured to utilize the faulty bit information to facilitate decode operations. The error correction circuitry may then provide bit error information that may then be utilized by the defect map logic to identify a faulty WL and/or a faulty BL.

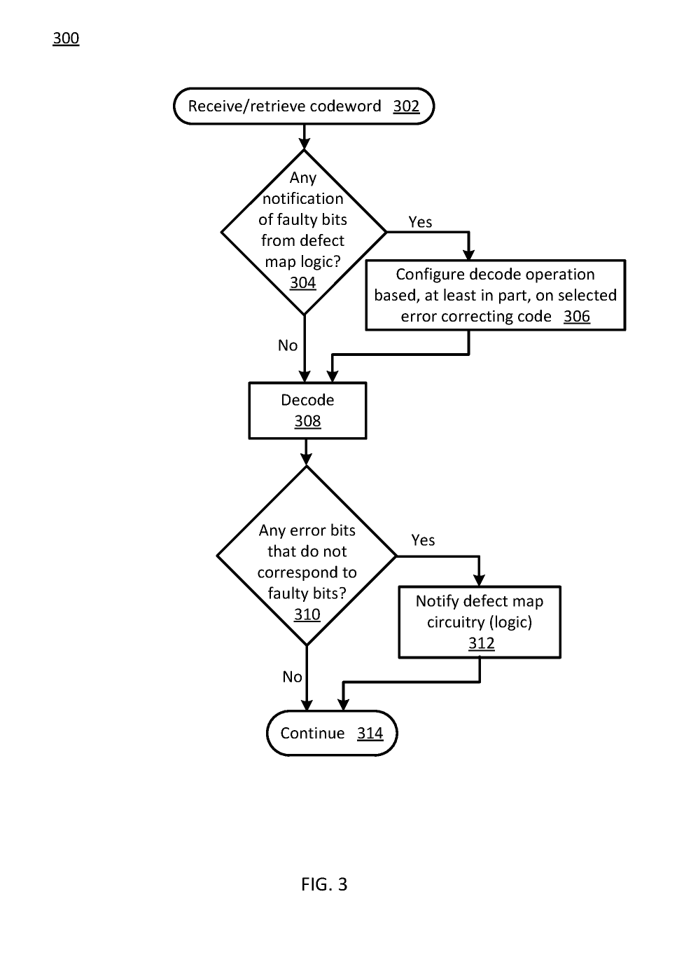

FIG. 3 is a flowchart 300 of error correction operations according to various embodiments of the present disclosure. In particular, the flowchart 300 illustrates decoding a codeword based, at least in part, on an indication of faulty bit(s) provided by defect map logic. The operations may be performed, for example, by error correction circuitry 112, of FIG. 1A.

Operations of this embodiment may begin with receiving or retrieving a codeword at operation 302. For example, the codeword may be received from or retrieved from memory controller control circuitry. Whether a notification of faulty bits has been received from defect map logic may be determined at operation 304. If a notification of faulty bit(s) has been received, then a decode operation may be configured based, at least in part, on a selected error correcting code at operation 306. In one example, the faulty bit(s) may be erased, if the error correcting code complies and/or is compatible with LDPC or Reed Solomon. In another example, the decode operation may be configured to attempt to decode the codeword using at least a portion of a number of possible values of the faulty bit(s), if the error correcting code complies and/or is compatible with BCH. Program flow may then proceed to operation 308. If there is not a notification of faulty bits, program flow may proceed to operation 308. The codeword may be decoded at operation 308. Whether the codeword contains any error bits that do not correspond to faulty bits may be determined at operation 310. If the codeword does not contain any error bits that do not correspond to faulty bits, program flow may continue at operation 314. If the codeword does contain error bits that do not correspond to faulty bits then defect map circuitry (logic) may be notified at operation 312. Program flow may then proceed to operation 314.

Thus, a decode operation may be configured based, at least in part, on a selected error correcting code in response to an indication of faulty bits.

While the flowchart of FIGS. 2A, 2B and 3 illustrate operations according various embodiments, it is to be understood that not all of the operations depicted in FIGS. 2A, 2B and 3 are necessary for other embodiments. In addition, it is fully contemplated herein that in other embodiments of the present disclosure, the operations depicted in FIGS. 2A, 2B and/or 3 and/or other operations described herein may be combined in a manner not specifically shown in any of the drawings, and such embodiments may include less or more operations than are illustrated in FIGS. 2A, 2B and 3. Thus, claims directed to features and/or operations that are not exactly shown in one drawing are deemed within the scope and content of the present disclosure.

As used in any embodiment herein, the term “logic” may refer to an app, software, firmware and/or circuitry configured to perform any of the aforementioned operations. Software may be embodied as a software package, code, instructions, instruction sets and/or data recorded on non-transitory computer readable storage medium. Firmware may be embodied as code, instructions or instruction sets and/or data that are hard-coded (e.g., nonvolatile) in memory devices.

“Circuitry,” as used in any embodiment herein, may comprise, for example, singly or in any combination, hardwired circuitry, programmable circuitry such as computer processors comprising one or more individual instruction processing cores, state machine circuitry, logic and/or firmware that stores instructions executed by programmable circuitry. The circuitry may be embodied as an integrated circuit, such as an integrated circuit chip. In some embodiments, the circuitry may be formed, at least in part, by the processor circuitry 102 executing code and/or instructions sets (e.g., software, firmware, etc.) corresponding to the functionality described herein, thus transforming a general-purpose processor into a specific-purpose processing environment to perform one or more of the operations described herein. In some embodiments, the various components and circuitry of the memory controller circuitry or other systems may be combined in a system-on-a-chip (SoC) architecture.

The foregoing provides example system architectures and methodologies, however, modifications to the present disclosure are possible. The processor may include one or more processor cores and may be configured to execute system software. System software may include, for example, an operating system. Device memory may include I/O memory buffers configured to store one or more data packets that are to be transmitted by, or received by, a network interface.

The operating system (OS) may be configured to manage system resources and control tasks that are run on, e.g., system 100. For example, the OS may be implemented using Microsoft® Windows®, HP-UX®, Linux®, or UNIX®, although other operating systems may be used. In another example, the OS may be implemented using Android™, iOS, Windows Phone® or BlackBerry®. In some embodiments, the OS may be replaced by a virtual machine monitor (or hypervisor) which may provide a layer of abstraction for underlying hardware to various operating systems (virtual machines) running on one or more processing units. The operating system and/or virtual machine may implement a protocol stack. A protocol stack may execute one or more programs to process packets. An example of a protocol stack is a TCP/IP (Transport Control Protocol/Internet Protocol) protocol stack comprising one or more programs for handling (e.g., processing or generating) packets to transmit and/or receive over a network.

The defect map circuitry memory 124 may include one or more of the following types of memory: semiconductor firmware memory, programmable memory, non-volatile memory, read only memory, electrically programmable memory, random access memory, flash memory, magnetic disk memory, and/or optical disk memory. Either additionally or alternatively system memory may include other and/or later-developed types of computer-readable memory.

Embodiments of the operations described herein may be implemented in a computer-readable storage device having stored thereon instructions that when executed by one or more processors perform the methods. The processor may include, for example, a processing unit and/or programmable circuitry. The storage device may include a machine readable storage device including any type of tangible, non-transitory storage device, for example, any type of disk including floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic and static RAMs, erasable programmable read-only memories (EPROMs), electrically erasable programmable read-only memories (EEPROMs), flash memories, magnetic or optical cards, or any type of storage devices suitable for storing electronic instructions.

In some embodiments, a hardware description language (HDL) may be used to specify circuit and/or logic implementation(s) for the various logic and/or circuitry described herein. For example, in one embodiment the hardware description language may comply or be compatible with a very high speed integrated circuits (VHSIC) hardware description language (VHDL) that may enable semiconductor fabrication of one or more circuits and/or logic described herein. The VHDL may comply or be compatible with IEEE Standard 1076-1987, IEEE Standard 1076.2, IEEE1076.1, IEEE Draft 3.0 of VHDL-2006, IEEE Draft 4.0 of VHDL-2008 and/or other versions of the IEEE VHDL standards and/or other hardware description standards.

### EXAMPLES

Examples of the present disclosure include subject material such as a method, means for performing acts of the method, a device, or of an apparatus or system related to faulty word line and faulty bit line information in error correcting coding, as discussed below.

### Example 1

According to this example, there is provided a memory controller. The memory controller includes a memory controller control circuitry, a defect map logic and an error correction circuitry. The memory controller control circuitry is to read a codeword from a memory device. The defect map logic is to identify a respective word line (WL) and a respective bit line (BL) for each bit in the codeword based, at least in part, on a memory device map and to determine whether any identified WL and/or any identified BL is faulty based, at least in part, on a defect map. The error correction circuitry is to configure a decode operation if any identified WL and/or any identified BL is faulty.

### Example 2

This example includes the elements of example 1, wherein the defect map logic is to determine whether a WL and/or a BL is faulty based, at least in part, on a respective WL bit error data and/or a respective BL bit error data; and to update the defect map if the WL is faulty and/or the BL is faulty.

### Example 3

This example includes the elements of example 2, wherein determining whether the WL and/or BL is faulty includes determining a raw bit error rate (RBER) for the WL and/or the BL.

### Example 4

This example includes the elements of example 1 or 2, wherein the error correction circuitry is to notify the defect map logic if the codeword contains an error bit that is not a faulty bit associated with the identified WL and/or the identified BL.

### Example 5

This example includes the elements of example 1 or 2, wherein to configure the decode operation is based, at least in part, on a selected error correcting code.

### Example 6

This example includes the elements of example 5, wherein the error correcting code includes a low density parity check (LDPC) error correcting code, a Reed Solomon error correcting code or a Bose-Chaudhuri-Hocquenghem (BCH) error correcting code.

### Example 7

This example includes the elements of example 5, wherein the selected error correcting code is LDPC or Reed Solomon and the error correction circuitry is to erase each faulty bit of the codeword, each faulty bit associated with an identified faulty WL and/or an identified faulty BL.

### Example 8

This example includes the elements of example 5, wherein the selected error correcting code is BCH and the error correction circuitry is to attempt to decode the codeword using at least a portion of a number of possible values of one or more faulty bits of the codeword, each faulty bit associated with an identified faulty WL and/or an identified faulty BL.

### Example 9

This example includes the elements of example 2, wherein the defect map logic is to update the WL bit error data if the WL is faulty and/or the BL bit error data if the BL is faulty.

### Example 10

This example includes the elements of example 1 or 2, wherein a plurality of bits in the codeword are distributed across the memory device.

### Example 11

According to this example, there is provided a method. The method includes reading, by a memory controller control circuitry, a codeword from a memory device; identifying, by a defect map logic, a respective word line (WL) and a respective bit line (BL) for each bit in the codeword based, at least in part, on a memory device map; determining, by the defect map logic, whether any identified WL and/or any identified BL is faulty based, at least in part, on a defect map; and configuring, by an error correction circuitry, a decode operation if any identified WL and/or any identified BL is faulty.

### Example 12

This example includes the elements of example 11, further including determining, by the defect map logic, whether a WL and/or a BL is faulty based, at least in part, on a respective WL bit error data and/or a respective BL bit error data; and updating, by the defect map logic, the defect map if the WL is faulty and/or the BL is faulty.

### Example 13

This example includes the elements of example 12, wherein determining whether the WL and/or BL is faulty includes determining a raw bit error rate (RBER) for the WL and/or the BL.

### Example 14

This example includes the elements of example 11, further including notifying, by the error correction circuitry, the defect map logic if the codeword contains an error bit that is not a faulty bit associated with the identified WL and/or the identified BL.

### Example 15

This example includes the elements of example 11, wherein the configuring is based, at least in part, on a selected error correcting code.

### Example 16

This example includes the elements of example 15, wherein the error correcting code includes a low density parity check (LDPC) error correcting code, a Reed Solomon error correcting code or a Bose-Chaudhuri-Hocquenghem (BCH) error correcting code.

### Example 17

This example includes the elements of example 15, wherein the selected error correcting code is LDPC or Reed Solomon and the error correction circuitry is to erase each faulty bit of the codeword, each faulty bit associated with an identified faulty WL and/or an identified faulty BL.

### Example 18

This example includes the elements of example 15, wherein the selected error correcting code is BCH and the error correction circuitry is to attempt to decode the codeword using at least a portion of a number of possible values of one or more faulty bits of the codeword, each faulty bit associated with an identified faulty WL and/or an identified faulty BL.

### Example 19

This example includes the elements of example 12, further including updating, by the defect map logic, the WL bit error data if the WL is faulty and/or the BL bit error data if the BL is faulty.

### Example 20

This example includes the elements of example 11, wherein a plurality of bits in the codeword are distributed across the memory device.

### Example 21

According to this example, there is provided a system. The system includes a memory device and a memory controller. The memory controller includes a memory controller control circuitry, a defect map logic and an error correction circuitry. The memory controller control circuitry is to read a codeword from the memory device. The defect map logic is to identify a respective word line (WL) and a respective bit line (BL) for each bit in the codeword based, at least in part, on a memory device map and to determine whether any identified WL and/or any identified BL is faulty based, at least in part, on a defect map. The error correction circuitry is to configure a decode operation if any identified WL and/or any identified BL is faulty.

### Example 22

This example includes the elements of example 21, wherein the defect map logic is to determine whether a WL and/or a BL is faulty based, at least in part, on a respective WL bit error data and/or a respective BL bit error data; and to update the defect map if the WL is faulty and/or the BL is faulty.

### Example 23

This example includes the elements of example 22, wherein determining whether the WL and/or BL is faulty includes determining a raw bit error rate (RBER) for the WL and/or the BL.

### Example 24

This example includes the elements of example 21 or 22, wherein the error correction circuitry is to notify the defect map logic if the codeword contains an error bit that is not a faulty bit associated with the identified WL and/or the identified BL.

### Example 25

This example includes the elements of example 21 or 22, wherein to configure the decode operation is based, at least in part, on a selected error correcting code.

### Example 26

This example includes the elements of example 25, wherein the error correcting code includes a low density parity check (LDPC) error correcting code, a Reed Solomon error correcting code or a Bose-Chaudhuri-Hocquenghem (BCH) error correcting code.

### Example 27

This example includes the elements of example 25, wherein the selected error correcting code is LDPC or Reed Solomon and the error correction circuitry is to erase each faulty bit of the codeword, each faulty bit associated with an identified faulty WL and/or an identified faulty BL.

### Example 28

This example includes the elements of example 25, wherein the selected error correcting code is BCH and the error correction circuitry is to attempt to decode the codeword using at least a portion of a number of possible values of one or more faulty bits of the codeword, each faulty bit associated with an identified faulty WL and/or an identified faulty BL.

### Example 29

This example includes the elements of example 22, wherein the defect map logic is to update the WL bit error data if the WL is faulty and/or the BL bit error data if the BL is faulty.

### Example 30

This example includes the elements of example 21 or 22, wherein a plurality of bits in the codeword are distributed across the memory device.

### Example 31

According to this example, there is provided a computer readable storage device. The device has stored thereon instructions that when executed by one or more processors result in the following operations including: reading a codeword from a memory device; identifying a respective word line (WL) and a respective bit line (BL) for each bit in the codeword based, at least in part, on a memory device map; determining whether any identified WL and/or any identified BL is faulty based, at least in part, on a defect map; and configuring a decode operation if any identified WL and/or any identified BL is faulty.

### Example 32

This example includes the elements of example 31, wherein the instructions that when executed by one or more processors results in the following additional operations including determining, by the defect map logic, whether a WL and/or a BL is faulty based, at least in part, on a respective WL bit error data and/or a respective BL bit error data; and updating, by the defect map logic, the defect map if the WL is faulty and/or the BL is faulty.

### Example 33

This example includes the elements of example 32, wherein determining whether the WL and/or BL is faulty includes determining a raw bit error rate (RBER) for the WL and/or the BL.

### Example 34

This example includes the elements of example 31 or 32, wherein the instructions that when executed by one or more processors results in the following additional operations including notifying, by the error correction circuitry, the defect map logic if the codeword contains an error bit that is not a faulty bit associated with the identified WL and/or the identified BL.

### Example 35

This example includes the elements of example 31 or 32, wherein the configuring is based, at least in part, on a selected error correcting code.

### Example 36

This example includes the elements of example 35, wherein the error correcting code includes a low density parity check (LDPC) error correcting code, a Reed Solomon error correcting code or a Bose-Chaudhuri-Hocquenghem (BCH) error correcting code.

### Example 37

This example includes the elements of example 35, wherein the selected error correcting code is LDPC or Reed Solomon and the error correction circuitry is to erase each faulty bit of the codeword, each faulty bit associated with an identified faulty WL and/or an identified faulty BL.

### Example 38

This example includes the elements of example 35, wherein the selected error correcting code is BCH and the error correction circuitry is to attempt to decode the codeword using at least a portion of a number of possible values of one or more faulty bits of the codeword, each faulty bit associated with an identified faulty WL and/or an identified faulty BL.

### Example 39

This example includes the elements of example 32, wherein the instructions that when executed by one or more processors results in the following additional operations including updating the WL bit error data if the WL is faulty and/or the BL bit error data if the BL is faulty.

### Example 40

This example includes the elements of example 31 or 32, wherein a plurality of bits in the codeword are distributed across the memory device.

### Example 41

According to this example, there is provided a device. The device includes means for reading, by a memory controller control circuitry, a codeword from a memory device; means for identifying, by a defect map logic, a respective word line (WL) and a respective bit line (BL) for each bit in the codeword based, at least in part, on a memory device map; means for determining, by the defect map logic, whether any identified WL and/or any identified BL is faulty based, at least in part, on a defect map; and means for configuring, by an error correction circuitry, a decode operation if any identified WL and/or any identified BL is faulty.

### Example 42

This example includes the elements of example 41, further including means for determining, by the defect map logic, whether a WL and/or a BL is faulty based, at least in part, on a respective WL bit error data and/or a respective BL bit error data; and means for updating, by the defect map logic, the defect map if the WL is faulty and/or the BL is faulty.

### Example 43

This example includes the elements of example 42, wherein determining whether the WL and/or BL is faulty includes determining a raw bit error rate (RBER) for the WL and/or the BL.

### Example 44

This example includes the elements of example 41 or 42, further including means for notifying, by the error correction circuitry, the defect map logic if the codeword contains an error bit that is not a faulty bit associated with the identified WL and/or the identified BL.

### Example 45

This example includes the elements of example 41 or 42, wherein the configuring is based, at least in part, on a selected error correcting code.

### Example 46

This example includes the elements of example 45, wherein the error correcting code includes a low density parity check (LDPC) error correcting code, a Reed Solomon error correcting code or a Bose-Chaudhuri-Hocquenghem (BCH) error correcting code.

### Example 47

This example includes the elements of example 45, wherein the selected error correcting code is LDPC or Reed Solomon and the error correction circuitry is to erase each faulty bit of the codeword, each faulty bit associated with an identified faulty WL and/or an identified faulty BL.

### Example 48

This example includes the elements of example 45, wherein the selected error correcting code is BCH and the error correction circuitry is to attempt to decode the codeword using at least a portion of a number of possible values of one or more faulty bits of the codeword, each faulty bit associated with an identified faulty WL and/or an identified faulty BL.

### Example 49

This example includes the elements of example 42, further including means for updating, by the defect map logic, the WL bit error data if the WL is faulty and/or the BL bit error data if the BL is faulty.

### Example 50

This example includes the elements of example 41 or 42, wherein a plurality of bits in the codeword are distributed across the memory device.

### Example 51

This example includes the elements of example 21 or 22, further including processor circuitry.

### Example 52

According to this example, there is provided a system. The system includes at least one device arranged to perform the method of any one of examples 11 to 20.

### Example 53

According to this example, there is provided a device. The device includes means to perform the method of any one of examples 11 to 20.

### Example 54

According to this example, there is provided a computer readable storage device. The device has stored thereon instructions that when executed by one or more processors result in the following operations including: the method according to any one of examples 11 to 20.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

What is claimed is:

1. A memory controller comprising:
a memory controller control circuitry to read a codeword from a memory device;
a defect map logic to identify a respective word line (WL) and a respective bit line (BL) for each bit in the codeword based, at least in part, on a memory device map and to determine whether any identified WL and/or any identified BL is faulty based, at least in part, on a defect map; and
an error correction circuitry to configure a decode operation if any identified WL and/or any identified BL is faulty.

2. The memory controller of claim 1, wherein the defect map logic is to determine whether a WL and/or a BL is faulty based, at least in part, on a respective WL bit error data and/or a respective BL bit error data; and to update the defect map if the WL is faulty and/or the BL is faulty.

3. The memory controller of claim 2, wherein determining whether the WL and/or BL is faulty comprises determining a raw bit error rate (RBER) for the WL and/or the BL.

4. The memory controller of claim 1, wherein the error correction circuitry is to notify the defect map logic if the codeword contains an error bit that is not a faulty bit associated with the identified WL and/or the identified BL.

5. The memory controller of claim 1, wherein to configure the decode operation is based, at least in part, on a selected error correcting code.

6. The memory controller of claim 5, wherein the error correcting code comprises a low density parity check (LDPC) error correcting code, a Reed Solomon error correcting code or a Bose-Chaudhuri-Hocquenghem (BCH) error correcting code.

7. The memory controller of claim 5, wherein the selected error correcting code is LDPC or Reed Solomon and the error correction circuitry is to erase each faulty bit of the codeword, each faulty bit associated with an identified faulty WL and/or an identified faulty BL.

8. The memory controller of claim 5, wherein the selected error correcting code is BCH and the error correction circuitry is to attempt to decode the codeword using at least a portion of a number of possible values of one or more faulty bits of the codeword, each faulty bit associated with an identified faulty WL and/or an identified faulty BL.

9. A method comprising:
reading, by a memory controller control circuitry, a codeword from a memory device;
identifying, by a defect map logic, a respective word line (WL) and a respective bit line (BL) for each bit in the codeword based, at least in part, on a memory device map;
determining, by the defect map logic, whether any identified WL and/or any identified BL is faulty based, at least in part, on a defect map; and
configuring, by an error correction circuitry, a decode operation if any identified WL and/or any identified BL is faulty.

10. The method of claim 9, further comprising determining, by the defect map logic, whether a WL and/or a BL is faulty based, at least in part, on a respective WL bit error data and/or a respective BL bit error data; and updating, by the defect map logic, the defect map if the WL is faulty and/or the BL is faulty.

11. The method of claim 10, wherein determining whether the WL and/or BL is faulty comprises determining a raw bit error rate (RBER) for the WL and/or the BL.

12. The method of claim 9, further comprising notifying, by the error correction circuitry, the defect map logic if the codeword contains an error bit that is not a faulty bit associated with the identified WL and/or the identified BL.

13. The method of claim 9, wherein the configuring is based, at least in part, on a selected error correcting code.

14. The method of claim 13, wherein the error correcting code comprises a low density parity check (LDPC) error correcting code, a Reed Solomon error correcting code or a Bose-Chaudhuri-Hocquenghem (BCH) error correcting code.

15. The method of claim 13, wherein the selected error correcting code is LDPC or Reed Solomon and the error correction circuitry is to erase each faulty bit of the codeword, each faulty bit associated with an identified faulty WL and/or an identified faulty BL.

16. The method of claim 13, wherein the selected error correcting code is BCH and the error correction circuitry is to attempt to decode the codeword using at least a portion of a number of possible values of one or more faulty bits of the codeword, each faulty bit associated with an identified faulty WL and/or an identified faulty BL.

17. A system comprising:
a memory device; and
a memory controller including:
a memory controller control circuitry to read a codeword from the memory device;
a defect map logic to identify a respective word line (WL) and a respective bit line (BL) for each bit in the codeword based, at least in part, on a memory device map and to determine whether any identified WL and/or any identified BL is faulty based, at least in part, on a defect map; and
an error correction circuitry to configure a decode operation if any identified WL and/or any identified BL is faulty.

18. The system of claim 17, wherein the defect map logic is to determine whether a WL and/or a BL is faulty based, at least in part, on a respective WL bit error data and/or a respective BL bit error data; and to update the defect map if the WL is faulty and/or the BL is faulty.

19. The system of claim 18, wherein determining whether the WL and/or BL is faulty comprises determining a raw bit error rate (RBER) for the WL and/or the BL.

20. The system of claim 17, wherein the error correction circuitry is to notify the defect map logic if the codeword contains an error bit that is not a faulty bit associated with the identified WL and/or the identified BL.

21. The system of claim 17, wherein to configure the decode operation is based, at least in part, on a selected error correcting code.

22. The system of claim 21, wherein the error correcting code comprises a low density parity check (LDPC) error correcting code, a Reed Solomon error correcting code or a Bose-Chaudhuri-Hocquenghem (BCH) error correcting code.

23. The system of claim 21, wherein the selected error correcting code is LDPC or Reed Solomon and the error correction circuitry is to erase each faulty bit of the codeword, each faulty bit associated with an identified faulty WL and/or an identified faulty BL.

24. The system of claim 21, wherein the selected error correcting code is BCH and the error correction circuitry is to attempt to decode the codeword using at least a portion of a number of possible values of one or more faulty bits of the codeword, each faulty bit associated with an identified faulty WL and/or an identified faulty BL.
